(19) United States
(12) Patent Application Publication
(10) Pub. No.: US 2009/0078982 A1
(43) Pub. Date: Mar. 26, 2009

(54) ALPHA HYDROXY CARBOXYLIC ACID ETCHANTS FOR SILICON MICROSTRUCTURES

(76) Inventors: Willy Rachmady, Beaverton, OR (US); Carolyn Taylor, Beaverton, OR (US)

Correspondence Address: COOL PATENT, P.C.;c/o CPA Global, P.O. BOX 52050, MINNEAPOLIS, MN, 55402, US

(21) Appl. No.: 11/860,519

(22) Filed: Sep. 24, 2007

(51) Int. Cl. H01L 21/22; C09K 13/06; H01L 29/788

(52) U.S. Cl. 257/315; 252/79.4; 438/542; 257/E29.3; 257/E21.135

(57) ABSTRACT

α-Hydroxy carboxylic acid etchants for silicon microstructures are generally described. In one example, a method includes fabricating a protruding structure on a semiconductor substrate, the protruding structure comprising a first layer of silicon coupled with the semiconductor substrate, the first layer of silicon defining a bottom gate, a sacrificial layer of silicon germanium (SiGe) coupled with the first layer of silicon, and a second layer of silicon coupled with the layer of SiGe, fabricating a top gate that traverses the protruding structure, and selectively etching the sacrificial layer of SiGe using an etchant including hydrofluoric acid (HF), nitric acid (HNO₃), and an α-hydroxy carboxylic acid to enable doping of at least the first layer of silicon prior to selectively etching the sacrificial layer of SiGe.

### BACKGROUND

Generally, selective wet etchants are used to etch silicon germanium (SiGe) in the fabrication of semiconductor devices such as floating body cell (FBC) transistors, for example.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a structural formula of an α-hydroxy carboxylic acid, according to but one embodiment;

FIGS. 2a-2c depict an application of an α-hydroxy carboxylic acid etchant for silicon microstructures, according to but one embodiment; and

FIG. 3 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of α-hydroxy carboxylic acid etchants for silicon microstructures are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

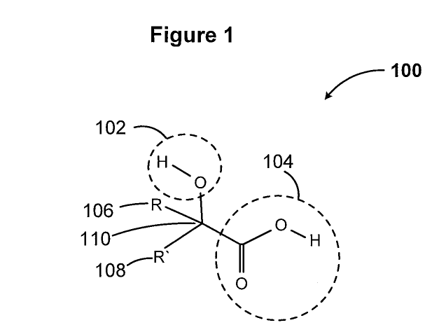

FIG. 1 is a structural formula of α-hydroxy carboxylic acid 100, according to but one embodiment. In an embodiment, an etchant includes an α-hydroxy carboxylic acid 100, the α-hydroxy carboxylic acid 100 including an α-hydroxyl group 102, a carboxyl group 104, functional group R 106, and functional group R′ 108, each coupled as shown. In an embodiment, an etchant includes hydrofluoric acid (HF), nitric acid (HNO₃), and an α-hydroxy carboxylic acid 100 to selectively etch silicon germanium (SiGe). In another embodiment, an α-hydroxy carboxylic acid 100 includes a carboxyl group 104 having a first carbon coupled with a second carbon atom 110, the second carbon atom 110 being coupled with a hydroxyl group 102, a first functional group R 106, and a second functional group R′ 108. In an embodiment, the first functional group R 106 or the second functional group R′ 108 includes hydrogen, alkyl or aryl functional groups, oxygen-containing functional groups, any suitable organic functional group, or suitable combinations thereof.

Current etchants used to etch SiGe in silicon microstructures may not be highly selective to doped silicon, which may result in corrosion or pitting of the doped silicon microstructures during SiGe etch. For example, SiGe may be currently etched in the fabrication of floating body cell (FBC) transistors prior to doping or implanting the silicon to avoid pitting or corrosion of silicon microstructures; however, doping or implanting after etching may be difficult due to geometric shadowing caused by gate structures or other process integration difficulties. An etchant using a normal carboxylic acid such as acetic acid, for example, may be used to etch SiGe, but its selectivity is degraded when silicon is doped. Providing a SiGe etchant with high or perfect selectivity to doped silicon may enable fabrication of silicon microstructures where silicon doping is accomplished prior to etching SiGe facilitating process integration.

A SiGe etchant according to embodiments described herein may be a selective wet etchant to etch sacrificial SiGe in the fabrication of FBC transistors on bulk silicon wafers for embedded memory applications. In an embodiment, a SiGe etchant achieves very high, complete, near perfect, or perfect selectivity to doped silicon by using one or more α-hydroxy carboxylic acids 100 as the medium for HF and HNO₃. In an embodiment, a SiGe etchant further includes water. In an embodiment, an etchant including α-hydroxy carboxylic acid 100 as the medium for HF and HNO₃ enables the fabrication of an FBC transistor with improved silicon interface and microstructure. In an embodiment, an etchant including HF/HNO₃ with α-hydroxy carboxylic acid 100 provides perfect selectivity to doped silicon to reduce pitting or corrosion of doped silicon. An etchant including α-hydroxy carboxylic acid 100 as the medium for HF and HNO₃ may enable doping of silicon prior to etching SiGe.

In other embodiments, an etchant including α-hydroxy carboxylic acid 100 as the medium for HF and HNO₃ is used to selectively etch SiGe in other silicon microstructures such as a Micro-Electro-Mechanical Systems (MEMS) cantilever, for example. Other SiGe and doped silicon microstructures fall within the spirit and scope of this description.

In an embodiment, α-hydroxy carboxylic acid 100 includes citric acid, lactic acid, malic acid, tartaric acid, or suitable combinations thereof. An etchant including o-hydroxy carboxylic acid 100 as the medium for HF and HNO₃ may maintain perfect or complete selectivity to doped silicon for a wide range of HF and HNO₃ concentrations, providing a wide process window. In an embodiment, an etchant using α-hydroxy carboxylic acid 100 includes about 1 to 5 wt % of HF, about 25 to 75 wt % of HNO₃, and about 20 to 75 wt % of α-hydroxy carboxylic acid. In an embodiment, a higher concentration of HF enables a higher etch rate.

In an embodiment, an etchant including α-hydroxy carboxylic acid 100, HF, and HNO₃ provides etch selectivity to doped silicon that is independent of doping concentration. This characteristic may enable integration of devices having different doping concentrations such as devices with different threshold voltages including p-type devices and n-type devices. In an embodiment, p-type devices are doped with boron and n-type devices are doped with arsenic, phosphorous, or suitable combinations thereof.

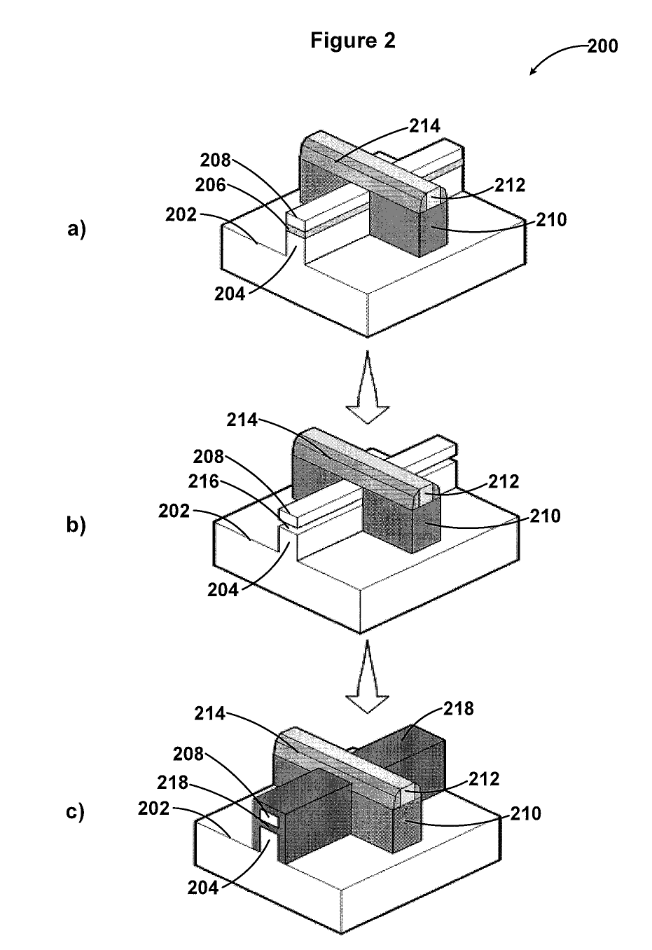

FIGS. 2a-2c depict an application of etchant including α-hydroxy carboxylic acid for silicon microstructures 200, according to but one embodiment. In an embodiment according to FIG. 2a, a silicon microstructure includes a semiconductor substrate 202, a protruding structure (hereafter called “fin”) or fin including a first layer of silicon 204 defining a bottom gate, a layer of SiGe 206, and a second layer of silicon 208, dielectric 210, top gate 212, and dielectric spacer 214, each coupled as shown.

FIG. 2a also provides a basis for describing a method. In an embodiment, a method 200 includes fabricating a fin 204, 206, 208 upon a semiconductor substrate 202, the fin including a first layer of silicon 204 coupled with the semiconductor substrate 202, the first layer of silicon 204 defining a bottom gate, a sacrificial layer of SiGe 206 coupled with the first layer of silicon 204, and a second layer of silicon 208 coupled with the layer of SiGe 206. In an embodiment, a method 200 includes fabricating a top gate 212 that traverses the fin 204, 206, 208. The top gate may run about perpendicular to the fin 204, 206, 208 across the top of the fin 204, 206, 208 as so depicted. A method may further include fabricating a dielectric support pillar 210 for top gate 212 and/or fabricating a dielectric spacer 214. A semiconductor substrate 202 may include silicon among other materials. In other embodiments, a top gate 212 includes polysilicon, a dielectric spacer 214 includes nitride, and pillar 210 includes oxide. Other suitable materials may be used in other embodiments.

In an embodiment according to FIGS. 2a-2b, a method 200 includes selectively etching the sacrificial layer of SiGe 206 using an etchant including HF, HNO₃, and α-hydroxy carboxylic acid. Selective etching may leave an air gap 216 in place of the SiGe layer 206, making a floating body silicon structure from the second layer of silicon 208 between the top gate 212 and the bottom gate 204. In an embodiment according to FIG. 2c, a method includes forming, growing, or depositing a dielectric material 218 as depicted. In an embodiment, a method includes forming a dielectric layer 218 in the area where SiGe has been selectively removed by etching 216. In an embodiment, the dielectric material 218 is an oxide grown on the first 204 and second 208 layers of silicon.

In an embodiment, a method 200 includes doping at least the first layer of silicon 204 prior to selectively etching the SiGe layer 216 of the fin. Doping or implanting silicon microstructures prior to etching SiGe may facilitate process integration for fabricating silicon microstructures. Doping may include doping with boron for p-type devices or doping with arsenic or phosphorous for n-type devices, but is not limited in this regard and may include any suitable dopant. In an embodiment, selectively etching 216 with an etchant including hydrofluoric acid (HF), nitric acid (HNO₃), and an α-hydroxy carboxylic acid provides etch selectivity to at least the first layer of doped silicon 204, the etch selectivity being independent of doping concentration to enable integration of p-type and n-type devices.

Selectively etching SiGe 206, 216 may be part of the fabrication of one or more floating body cell transistors on a bulk silicon wafer 202. In an embodiment, an etchant including α-hydroxy carboxylic acid provides perfect selectivity to doped silicon to reduce pitting or corrosion of at least the first layer of doped silicon 204. In another embodiment, such etchant enables doping of the first layer of silicon 204 prior to selectively etching the SiGe layer 206, 216.

In an embodiment, selectively etching SiGe 206, 216 includes using α-hydroxy carboxylic acids such as citric acid, lactic acid, malic acid, tartaric acid, or suitable combinations thereof. In another embodiment selectively etching SiGe 206, 216 is accomplished by using an etchant having about 1 to 5 wt % of HF, about 25 to 75 wt % of HNO₃, and about 20 to 75 wt % of α-hydroxy carboxylic acid. An etchant to selectively etch SiGe 206, 216 may accord with embodiments already described with respect to FIG. 1. A product formed using methods described with respect to FIGS. 2a-2c is also disclosed.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

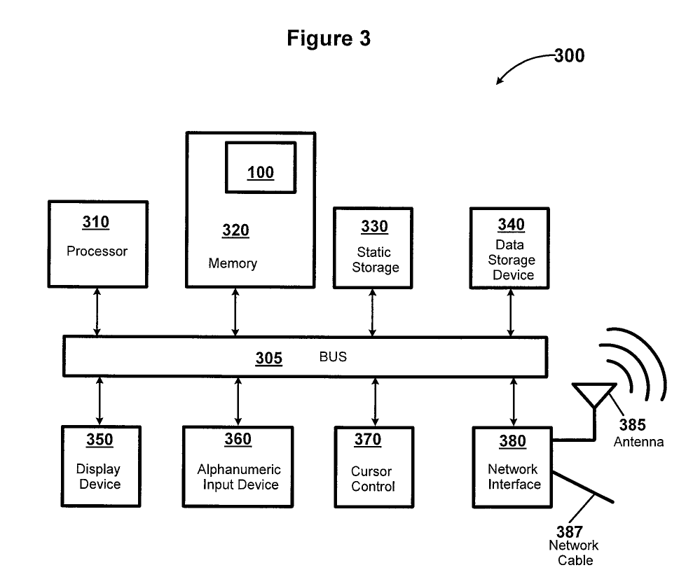

FIG. 3 is a diagram of an example system in which embodiments of the present invention may be used, according to but one embodiment. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 300 includes a semiconductor device or product made using α-hydroxy carboxylic acid etchant for silicon microstructures 100 in accordance with embodiments described with respect to FIGS. 1-2. In an embodiment, a semiconductor device or product made using α-hydroxy carboxylic acid etchant for silicon microstructures 100 is part of an electronic system's memory 320 or processor 310.

Electronic system 300 may include bus 305 or other communication device to communicate information, and processor 310 coupled to bus 305 that may process information. While electronic system 300 may be illustrated with a single processor, system 300 may include multiple processors and/or co-processors. In an embodiment, processor 310 includes a semiconductor device or product made using α-hydroxy carboxylic acid etchant for silicon microstructures 100 in accordance with embodiments described herein. System 300 may also include random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one embodiment. In another embodiment, memory 320 includes a semiconductor device or product made using α-hydroxy carboxylic acid etchant for silicon microstructures 100 as disclosed herein.

System 300 may also include read only memory (ROM) and/or other static storage device 330 coupled to bus 305 that may store static information and instructions for processor 310. Data storage device 340 may be coupled to bus 305 to store information and instructions. Data storage device 340 such as a magnetic disk or optical disc and corresponding drive may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may include one or more network interfaces 380 to provide access to network, such as a local area network. Network interface 380 may include, for example, a wireless network interface having antenna 385, which may represent one or more antennae. Network interface 380 may also include, for example, a wired network interface to communicate with remote devices via network cable 387, which may be, for example, an Ethernet cable, a coaxial cable, a fiber optic cable, a serial cable, or a parallel cable.

In one embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 380 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 300 includes one or more omnidirectional antennae 385, which may refer to an antenna that is at least partially omnidirectional and/or substantially omnidirectional, and a processor 310 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. A method comprising:
fabricating a protruding structure on a semiconductor substrate, the protruding structure comprising a first layer of silicon coupled with the semiconductor substrate, the first layer of silicon defining a bottom gate, a sacrificial layer of silicon germanium (SiGe) coupled with the first layer of silicon, and a second layer of silicon coupled with the layer of SiGe;
fabricating a top gate that traverses the protruding structure; and
selectively etching the sacrificial layer of SiGe using an etchant comprising hydrofluoric acid (HF), nitric acid (HNO₃), and an α-hydroxy carboxylic acid to enable doping of at least the first layer of silicon prior to selectively etching the sacrificial layer of SiGe.

2. A method according to claim 1 further comprising:
doping at least the first layer of silicon prior to selectively etching the SiGe layer.

3. A method according to claim 2 wherein doping comprises doping with boron for p-type devices or doping with arsenic or phosphorous for n-type devices and wherein selectively etching with an etchant comprising hydrofluoric acid (HF), nitric acid (HNO₃), and an α-hydroxy carboxylic acid provides etch selectivity to at least the first layer of doped silicon, the etch selectivity being independent of doping concentration to enable integration of p-type and n-type devices.

4. A method according to claim 2 wherein selectively etching the SiGe layer is part of the fabrication of one or more floating body cell transistors on a bulk silicon wafer wherein the etchant provides perfect selectivity to doped silicon to reduce pitting or corrosion of at least the first layer of doped silicon or enables doping of the first layer of silicon prior to selectively etching the SiGe layer, or suitable combinations thereof.

5. A method according to claim 1 wherein the α-hydroxy carboxylic acid used in selectively etching comprises citric acid, lactic acid, malic acid, tartaric acid, or suitable combinations thereof.

6. A method according to claim 1 wherein selectively etching the sacrificial layer of SiGe is accomplished by using an etchant comprising about 1 to 5 wt % of HF, about 25 to 75 wt % of HNO₃, and about 20 to 75 wt % of α-hydroxy carboxylic acid.

7. A method according to claim 1 wherein the semiconductor substrate comprises silicon and wherein the top gate comprises polysilicon, the polysilicon being coupled with a dielectric spacer, the top gate being supported by a pillar of oxide coupled with the semiconductor substrate.

8. A method according to claim 1 wherein selectively etching leaves an air gap in place of the SiGe layer and makes a floating body silicon structure from the second layer of silicon between the top gate and the bottom gate, the method further comprising:
forming a dielectric layer in the area where SiGe has been selectively removed by etching.

9. A product fabricated by the method of claim 8.

10. An etchant comprising:
hydrofluoric acid (HF);
nitric acid (HNO₃); and
an α-hydroxy carboxylic acid to serve as a medium to selectively etch silicon germanium (SiGe) wherein the α-hydroxy carboxylic acid comprises a carboxyl group having a first carbon atom coupled with a second carbon atom, the second carbon atom being coupled with a hydroxyl group, a first functional group, and a second functional group.

11. An etchant according to claim 10 wherein the α-hydroxy carboxylic acid comprises citric acid, lactic acid, malic acid, tartaric acid, or suitable combinations thereof.

12. An etchant according to claim 10 wherein the HF, HNO₃, and α-hydroxy carboxylic acid are used to selectively etch SiGe in the fabrication of one or more floating body cell transistors on bulk silicon wafers for embedded memory applications wherein using an α-hydroxy carboxylic acid medium provides perfect selectivity to doped silicon to reduce pitting or corrosion of doped silicon or to enable doping of silicon prior to etching SiGe, or suitable combinations thereof.

13. An etchant according to claim 10 comprising about 1 to 5 wt % of HF, about 25 to 75 wt % of HNO₃, and about 20 to 75 wt % of α-hydroxy carboxylic acid.

14. An etchant according to claim 10 wherein the α-hydroxy carboxylic acid provides etch selectivity to doped silicon that is independent of doping concentration to enable integration of p-type and n-type devices.

15. An etchant according to claim 10 wherein the first functional group or second functional group comprises hydrogen, alkyl or aryl functional groups, or suitable combinations thereof.
